(19) United States
(12) Patent Application Publication
(10) Pub. No.: US 2013/0319496 A1
(43) Pub. Date: Dec. 5, 2013

(54) LOW-METAL CONTENT ELECTROCONDUCTIVE PASTE COMPOSITION

(71) Applicant: Heraeus Precious Metals North America Conshohocken LLC, (US)

(72) Inventors: Lindsey A. KARPOWICH, Philadelphia, PA (US); Weiming ZHANG, Blue Bell, PA (US)

(73) Assignee: Heraeus Precious Metals North America Conshohocken LLC, West Conshohocken, PA (US)

(21) Appl. No.: 13/648,724

(22) Filed: Oct. 10, 2012

Related U.S. Application Data
(60) Provisional application No. 61/654,445, filed on Jun. 1, 2012.

(51) Int. Cl. H01B 1/22; H01L 31/042; H01L 31/18; H01L 31/0224

(52) U.S. Cl. 136/244; 136/256; 252/514; 252/512; 438/57; 257/E31.124

(57) ABSTRACT

An electroconductive paste for use in solar cell technology comprising a first silver particle that is less than one micron in size and having a surface area of greater than 2.4 m²/g, as well as glass frit and an organic vehicle. Another embodiment of the invention relates to an electroconductive paste for use in solar cell technology further comprising a second silver particle that is greater than one micron in size and having a surface area of less than 2 m²/g. According to another embodiment, the total silver content of the paste is less than about 83.5 wt. %. Another embodiment of the invention relates to a solar cell comprising a silicon wafer having at having a surface electrode comprising the electroconductive pastes according to the invention. Another embodiment of the invention relates to a solar cell module comprising electrically interconnected solar cells according to the invention. Yet another embodiment of the invention relates to a method of producing a solar cell by applying an electroconductive paste according to the invention to a silicon wafer and firing the wafer at an appropriate profile.

### CROSS-REFERENCE TO RELATED APPLICATIONS

This application claims priority to U.S. Provisional Application No. 61/654,445 filed Jun. 1, 2012, the disclosure of which is incorporated herein by reference.

### FIELD OF THE INVENTION

This invention relates to electroconductive pastes as utilized in solar panel technology. Specifically, in one aspect, the invention relates to an electroconductive paste composition which reduces silver deposition compared to conventional paste compositions, while delivering comparable or improved solar cell efficiency.

### BACKGROUND OF THE INVENTION

Solar cells are devices that convert the energy of light into electricity using the photovoltaic effect. Solar power is an attractive green energy source because it is sustainable and produces only non-polluting by-products. Accordingly, a great deal of research is currently being devoted to developing solar cells with enhanced efficiency while continuously lowering material and manufacturing costs. When light hits a solar cell, a fraction of the incident light is reflected by the surface and the remainder is transmitted into the solar cell. The photons of the transmitted light are absorbed by the solar cell, which is usually made of a semiconducting material such as silicon. The energy from the absorbed photons excites electrons of the semiconducting material from their atoms, generating electron-hole pairs. These electron-hole pairs are then separated by p-n junctions and collected by conductive electrodes which are applied on the solar cell surface.

The most common solar cells are those made of silicon. Specifically, a p-n junction is made from silicon by applying an n-type diffusion layer onto a p-type silicon substrate, coupled with two electrical contact layers or electrodes. In a p-type semiconductor, dopant atoms are added to the semiconductor in order to increase the number of free charge carriers (positive holes). Essentially, the doping material takes away weakly bound outer electrons from the semiconductor atoms. One example of a p-type semiconductor is silicon with a boron or aluminum dopant. Solar cells can also be made from n-type semiconductors. In an n-type semiconductor, the dopant atoms provide extra electrons to the host substrate, creating an excess of negative electron charge carriers. One example of an n-type semiconductor is silicon with a phosphorous dopant. In order to minimize reflection of the sunlight by the solar cell, an antireflection coating, such as silicon nitride, is applied to the n-type diffusion layer to increase the amount of light coupled into the solar cell.

Silicon solar cells typically have electroconductive pastes applied to both their front and back surfaces. As part of the metallization process, a rear contact is typically first applied to the silicon substrate, such as by screen printing a back side silver paste or silver/aluminum paste to form soldering pads. Next, an aluminum paste is applied to the entire back side of the substrate to form a back surface field (BSF), and the cell is then dried. Next, using a different type of electroconductive paste, a metal contact may be screen printed onto the front side antireflection layer to serve as a front electrode. This electrical contact layer on the face or front of the cell, where light enters, is typically present in a grid pattern made of “finger lines” and “bus bars,” rather than a complete layer, because the metal grid materials are typically not transparent to light. The silicon substrate with printed front side and back side paste is then fired at a temperature of approximately 700-975° C. After firing, the front side paste etches through the antireflection layer, forms electrical contact between the metal grid and the semiconductor, and converts the metal pastes to metal electrodes. On the back side, the aluminum diffuses into the silicon substrate, acting as a dopant which creates the BSF. The resulting metallic electrodes allow electricity to flow to and from solar cells connected in a solar panel.

To assemble a panel, multiple solar cells are connected in series and/or in parallel and the ends of the electrodes of the first cell and the last cell are preferably connected to output wiring. The solar cells are typically encapsulated in a transparent thermal plastic resin, such as silicon rubber or ethylene vinyl acetate. A transparent sheet of glass is placed on the front surface of the encapsulating transparent thermal plastic resin. A back protecting material, for example, a sheet of polyethylene terephthalate coated with a film of polyvinyl fluoride having good mechanical properties and good weather resistance, is placed under the encapsulating thermal plastic resin. These layered materials may be heated in an appropriate vacuum furnace to remove air, and then integrated into one body by heating and pressing. Furthermore, since solar cells are typically left in the open air for a long time, it is desirable to cover the circumference of the solar cell with a frame material consisting of aluminum or the like.

A typical electroconductive paste contains metallic particles, glass frit, and an organic vehicle. These components must be carefully selected to take full advantage of the theoretical potential of the resulting solar cell. For example, it is desirable to maximize the contact between the metallic paste and silicon surface, and the metallic particles themselves, so that the charge carriers can flow through the interface and finger lines to the bus bars. The glass particles in the composition etch through the antireflection coating layer, helping to build contacts between the metal and the P+ type Si. On the other hand, the glass must not be so aggressive that it shunts the p-n junction after firing. Thus, the goal is to minimize contact resistance while keeping the p-n junction intact so as to achieve improved efficiency. Known compositions have high contact resistance due to the insulating effect of the glass in the interface of the metallic layer and silicon wafer, as well as other disadvantages such as high recombination in the contact area. Further, the weight percentage of metallic particles used in the paste can affect the paste's printability. Usually, using a higher amount of metallic particles in the paste increases the paste's conductivity, but also increases the viscosity of the paste, which lowers its efficiency in the printing process. Further, pastes with higher metallic content, especially silver pastes, are more expensive, as the cost of silver has increased dramatically throughout recent years. Since silver-based pastes account for approximately 10-15% of the total cost per solar cell, pastes with lower silver content are desired.

International Publication No. WO 2007/089273 A1 discloses an electrode paste for use in the manufacture of solar cell technology. The paste comprises silver particles having a specific surface of 0.2-0.6 m²/g, glass frit, resin binder and thinner. The silver particles having the required specific surface are 80% mass or more.

International Publication No. WO 2010/148382 A1 discloses a conductive thick film composition used in the manufacture of solar cell devices. Specifically, the publication discloses the use of different combinations of silver particles with varying surface areas and particle sizes.

U.S. Pat. No. 5,378,408 discloses a lead-free thick film paste composition for use in heated window applications. The paste comprises electrically functional materials, preferably silver, that are about 0.1-10 microns in size.

Therefore, it is desirable to develop a low silver content paste, having optimal electrical performance properties. It is also desirable to develop a paste that allows for reduced deposition of the paste on a solar cell, thereby reducing the deposition of silver, while maintaining or improving electrical performance.

### SUMMARY OF THE INVENTION

An object of the invention is to develop an electroconductive paste having a low silver content, while still achieving optimal electrical performance properties. Another object of the invention is to develop a paste that allows for lower paste deposition on a solar cell, thereby reducing the amount of silver deposited, while maintaining or improving electrical performance.

The invention provides an electroconductive paste for forming surface electrodes on solar cells comprising a silver component comprising a first silver particle having an average particle size of less than one micron and a specific surface area of greater than 2.4 m²/g, as well as glass frit and an organic vehicle.

According to another aspect of the invention, the first silver particle has an average particle size of 0.05-1 micron and a specific surface area of 2.4-20 m²/g. More preferably the first silver particle has an average particle size of 0.1-0.8 microns and a specific surface area of 2.4-10 m²/g. Most preferably, the first silver particle has an average particle size of 0.1-0.5 microns and a specific surface area of 2.4-5 m²/g.

According to a further aspect of the invention, the silver component further comprises a second silver particle. According to another aspect of the invention, the second silver particle has an average particle size greater than 1 micron and a specific surface area of less than 2 m²/g. More preferably, the second silver particle has an average particle size of 1-50 microns and a specific surface area of 0.1-2 m²/g. Most preferably, the second silver particle has an average particle size of 1-20 microns and a specific surface area of 0.1-1.5 m²/g.

According to an additional aspect of the invention, the silver component is less than 83.5 wt. % of the paste. Preferably, the first silver particle is about 0.01-10 wt. % of paste. Preferably, the second silver particle is about 60-90 wt. % of paste.

According to another aspect of the invention, the glass frit is about 5 wt. % of paste. Preferably, the glass frit comprises lead oxide.

According to a further aspect of the invention, the organic vehicle is about 1-35 wt. % of paste. Preferably, the organic vehicle comprises a binder, a surfactant, an organic solvent, and a thixatropic agent.

According to another aspect of the invention, the thixatropic agent is about 0.01-20 wt. % of organic vehicle. More preferably, the thixatropic agent is about 5-20 wt. % of the organic vehicle.

The invention also provides an electroconductive paste for use in forming surface electrodes on solar cells comprising conductive metal particles, which are 40-90 wt. % of paste, as well as glass frit, and an organic vehicle, wherein the organic vehicle comprises a binder, a surfactant, an organic solvent, and a thixatropic agent, wherein the thixatropic agent is about 1 wt. % of paste.

The invention also provides a solar cell comprising a silicon wafer and a surface electrode produced from electroconductive pastes according to the invention.

The invention further provides a solar cell module comprising electrically interconnected solar cells of the invention.

The invention also provides a method of producing a solar cell comprising the steps of providing a silicon wafer, applying an electroconductive paste of the invention to the silicon wafer, and firing the silicon wafer according to an appropriate profile.

### BRIEF DESCRIPTION OF THE DRAWINGS

FIG. 1 is a comparison of Scanning Electron Microscopy (SEM) cross section view photographs of five fired silver finger lines, one having approximately 83 wt. % of silver (i), one having 2% less silver (ii), one having 3% less silver (iii), one with 6% less silver (iv), and the last having 7% less silver (v);

FIG. 2 is an SEM cross section view photograph of a printed and fired silver finger line comprising Exemplary Paste 26N;

FIG. 3 is an SEM cross section view photograph of a printed and fired silver finger line comprising Exemplary Paste 26O;

FIG. 4 is an SEM cross section view photograph of a printed and fired silver finger line comprising Exemplary Paste 26R; and

FIG. 5 is an SEM cross section view photograph of a printed and fired silver finger line comprising Exemplary Paste 26S.

### DETAILED DESCRIPTION

The invention relates to an electroconductive paste composition. Electroconductive paste compositions preferably comprise metallic particles, glass frit, and an organic vehicle. While not limited to such an application, such pastes may be used to form an electrical contact layer or electrode on a solar cell. Specifically, the pastes may be applied to the front side of a solar cell or to the back side of a solar cell.

One aspect of the invention relates to the composition of an electroconductive paste. A desired paste is one which is low in viscosity, allowing for fine line printability, but not so low in viscosity that it is unable to be printed into a uniform line. Further, it must have optimal electrical properties. Typically, pastes with lower metallic content have a lower viscosity, but also produce finger lines having lower conductivity. However, pastes with lower metallic content are less expensive to manufacture, as material costs for conductive particles are constantly increasing. Thus, an electroconductive paste with a low metallic content, having an acceptable level of printability, and resulting in optimal conductivity, is desired. One aspect of the electroconductive paste composition according to the invention is comprised of sub-micron silver particles having a specific surface area greater than 2 m²/g, as well as glass frit and an organic vehicle.

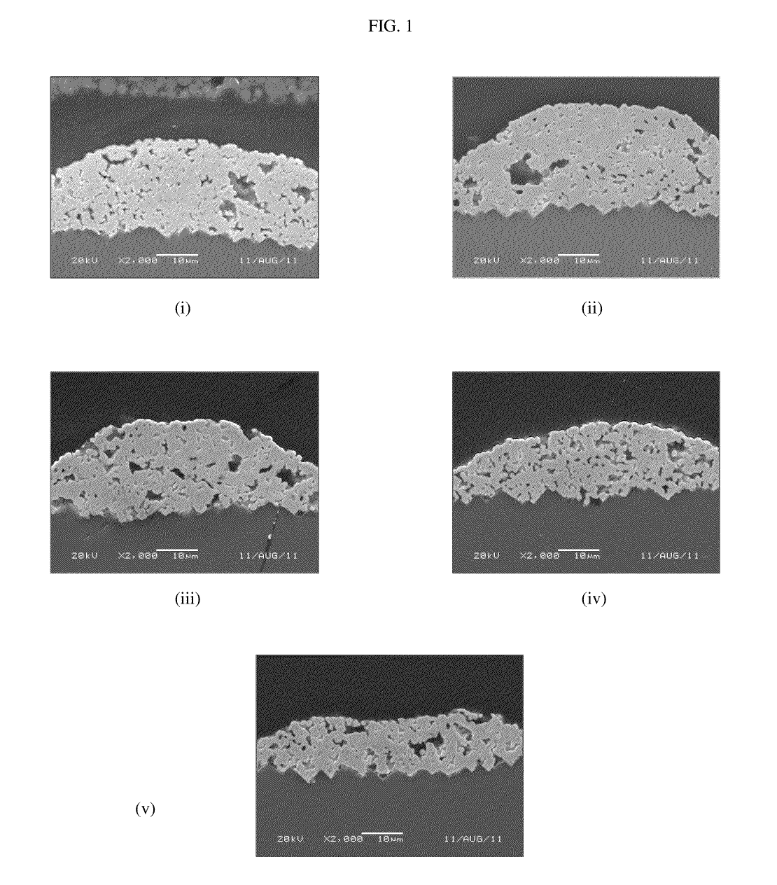

An electroconductive paste's electrical performance can be measured by its resistivity, or the level of opposition the paste exhibits to the passage of an electric current through the material. Typically, the lower the metallic content, the increase in series and grid resistance on the solar cell. Once the series resistance is increased to a certain point, the efficiency of the solar cell degrades to an unacceptable level. Further, as shown in FIG. 1, as silver content decreases, the line typically becomes more porous and too thin (decreased aspect ratio) to allow for optimal conduction. It is this increase in porosity and reduction in aspect ratio that are the likely cause of the increase in series and grid resistance. Therefore, a paste is desired that balances the need to reduce the amount of silver, thereby reducing manufacturing costs, without jeopardizing electrical performance.

A preferred embodiment of the invention is an electroconductive paste comprising a first silver particle having a particle size of less than 1 μm, as well as glass frit and organic vehicle. More preferably, the first silver particle has a particle size of 0.05-1 μm, and even more preferably the first silver particle has a particle size of 0.1-0.8 μm. In the most preferred embodiment, the first silver particle has an average particle size of 0.1-0.5 μm.

In another preferred embodiment, the first silver particle has a specific surface area of greater than 2.4 m²/g. More preferably, the first silver particle has a specific surface area of 2.4-20 m²/g, and even more preferably the first silver particle has a specific surface area of 2.4-10 m²/g. In the most preferred embodiment, the first silver particle has a specific surface area of 2.4-5 m²/g. The first silver particle is about 0.01-10 wt. % of paste.

Another embodiment of the invention is an electroconductive paste comprising the first silver particle as previously described, as well as a second silver particle having a particle size of greater than 1 μm and a specific surface area of less than 2 m²/g. Preferably, the second silver particle has a particle size of 1-50 μm and a specific surface area of 0.1-2 m²/g, and most preferably, the second silver particle has a particle size of 1-20 μm and a specific surface area of 0.1-1.5 m²/g. The second silver particle is about 60-90 wt. % of paste. In another preferred embodiment, the total silver content, including both the first and second silver particles, is less than 83.5 wt. % of paste. The electroconductive paste also comprises glass frit and an organic vehicle.

The glass frit is about 0.5-10 wt. % of the paste, preferably about 2-8 wt. %, more preferably about 5 wt. % of the paste, and can be lead-based or lead-free. The lead-based glass frit comprises lead oxide or other lead-based compounds including, but not limited to, salts of lead halides, lead chalcogenides, lead carbonate, lead sulfate, lead phosphate, lead nitrate and organometallic lead compounds or compounds that can form lead oxides or slats during thermal decomposition. The lead-free glass frit may include other oxides or compounds known to one skilled in the art. For example, silicon, boron, aluminum, bismuth, lithium, sodium, magnesium, zinc, titanium, or zirconium oxides or compounds may be used. Other glass matrix formers or glass modifiers, such as germanium oxide, vanadium oxide, tungsten oxide, molybdenum oxides, niobium oxides, tin oxides, indium oxides, other alkaline and alkaline earth metal (such as K, Rb, Cs and Be, Ca, Sr, Ba) compounds, rare earth oxides (such as La₂O₃, cerium oxides), phosphorus oxides or metal phosphates, transition metal oxides (such as copper oxides and chromium oxides), or metal halides (such as lead fluorides and zinc fluorides may also be part of the glass composition.

The organic vehicle comprises about 1-10 wt. % (of organic vehicle) binder, about 1-10 wt. % surfactant, about 50-70 wt. % organic solvent, and about 0.01-20 wt. % thixatropic agent. The particular composition of the organic vehicle is known to one skilled in the art. For example, a common binder for such applications is a cellulose or phenolic resin, and common solvents can be any of carbitol, terpineol, hexyl carbitol, texanol, butyl carbitol, butyl carbitol acetate, or dimethyladipate or glycol ethers. The organic vehicle also includes surfactants and thixatropic agents known to one skilled in the art. Surfactants can include, but are not limited to, polyethyleneoxide, polyethyleneglycol, benzotriazole, poly(ethyleneglycol)acetic acid, lauric acid, oleic acid, capric acid, myristic acid, linolic acid, stearic acid, palmitic acid, stearate salts, palmitate salts, and mixtures thereof. In sum, the organic vehicle is about 1-35 wt. % of paste.

Thixatropic agents (thiaxatropes) are used to adjust the viscosity of the paste composition. The paste composition exhibits a decreased viscosity while under mechanical stress, referred to as shear thinning. In one embodiment of the invention, increased thixatrope content improves the printability of the resulting low silver content paste. Preferably, the thixatrope content is above 1 wt. % of the total paste composition. More preferably, the thixatrope content is above 1.2 wt. % of paste. A wide range of thixatropic agents known to one skilled in the art, including gels and organics, are suitable for the invention. Thixatropic agents may be derived from natural origin, e.g., castor oil, or they may be synthesized. Commercially available thixatropic agents can also be used with the invention.

The electroconductive paste composition may be prepared by any method for preparing a paste composition known in the art. As an example, without limitation, the paste components may then be mixed, such as with a mixer, then passed through a three roll mill, for example, to make a dispersed uniform paste. Such a paste may then be utilized to form a solar cell by application of the paste to the antireflection layer on a silicon substrate, such as by screen printing, and then drying and firing to form an electrode (electrical contact) on the silicon substrate. The electroconductive paste is suitable to be used on p-type and also n-type silicon wafer.

### EXAMPLE 1

As shown in Table 1, a first set of exemplary pastes (referred to as 26A-26E) was prepared in order to ascertain the effect of decreasing the silver content of the paste on the resulting electrical performance. As the silver content was decreased, the organic vehicle formulation was changed slightly in order to compensate for the paste's viscosity. The same glass frit was used in each exemplary paste, although the amount of glass frit was also adjusted slightly as silver was decreased, in order to keep the ratio of silver to glass as consistent as possible. Once the components of the pastes were mixed, they were then milled using a three-roll mill until becoming a dispersed uniform paste.

TABLE 1
Composition of First Set of Exemplary Pastes

| | 26A | 26B | 26C | 26D | 26E |
|---|---|---|---|---|---|
| Silver (wt. % paste) | 83 | 82 | 80 | 78 | 77 |
| Glass frit (wt. % paste) | 5 | 4 | 4 | 4 | 4 |
| Organic Vehicle (wt. % paste) | 12 | 14 | 16 | 18 | 19 |

The resulting pastes were screen printed onto an approximately 243 cm² P-type silicon solar wafer having a standard 55-70 Ω/□ sheet resistance and a silicon nitride antireflection coating, at a speed of 150 mm/s, using screen 325 (mesh)×0.9 (mil, wire diameter)×0.6 (mil, emulsion thickness)×50 μm (finger line opening) (Calendar screen). The printed wafers were then dried at 150° C. An aluminum paste back surface field was printed on the backside of each wafer and dried at 175° C. The wafers were then fired at 800-850° C. in an IR belt furnace. All resulting solar cells were then tested using an I-V tester. A Xe arc lamp in the I-V tester was used to simulate sunlight with a known intensity and the front surface of the solar cell was irradiated to generate the I-V curve. Using this curve, various parameters common to this measurement method which provide for electrical performance comparison were determined, including solar cell efficiency (Eff), fill factor (FF), series resistance (Rs), series resistance under three standard lighting intensities (Rs3), and grid resistance (Rg). The resulting solar cells were also cross-sectioned and polished in order to obtain scanning electron microscopy (SEM) images.

The electrical performance of the five exemplary pastes (26A-26E) was analyzed. All data is set forth in Table 2. As the amount of silver content decreases in the exemplary pastes, the series and grid resistance consistently increase, as expected. Further, at the lowest silver content levels, the exemplary pastes experience decreased efficiency and fill factor.

TABLE 2
Electrical Performance of First Set of Exemplary Pastes

| | 26A | 26B | 26C | 26D | 26E |
|---|---|---|---|---|---|
| Eff (%) | 18.016 | 18.023 | 17.978 | 17.726 | 17.737 |
| FF (%) | 78.649 | 78.714 | 78.413 | 77.634 | 77.562 |
| Rs (Ω) | 0.00466 | 0.00472 | 0.00489 | 0.00514 | 0.00517 |
| Rs3 (Ω) | 0.00345 | 0.00339 | 0.00352 | 0.00429 | 0.00427 |
| Rg (mΩ) | 19.431 | 21.863 | 28.169 | 33.430 | 34.749 |

### EXAMPLE 2

As shown in Table 3, a second set of exemplary pastes (referred to as 26G-26N) were prepared, all having about 80 wt. % silver content. Exemplary pastes 26K-26N each incorporate a sub-micron silver particle having a specific surface area of 2-3 m²/g. Pastes 26K and 26L incorporate a de-agglomerated sub-micron silver powder (SA), while Pastes 26M and 26N incorporate a sub-micron silver powder in agglomerated form (SB). The same glass frit and vehicle formulation were used in each exemplary paste. Once the components of the pastes were mixed, they were then milled using a three-roll mill until becoming a dispersed uniform paste.

TABLE 3
Composition of Second Set of Exemplary Pastes

| | 26G | 26K | 26L | 26M | 26N |
|---|---|---|---|---|---|
| Ag (wt. % paste) | 80 | 78 | 77 | 78 | 77 |
| Particle size >1 μm | | | | | |
| Ag Powder, SA | — | 2 | 3.5 | — | — |
| (wt. % paste) | | | | | |
| Ag Powder, SB | — | — | — | 2 | 3.5 |
| (wt. % paste) | | | | | |
| Glass frit (wt. % paste) | 4 | 4 | 4 | 4 | 4 |
| Vehicle (wt. % paste) | ~15 | ~15 | ~14 | ~15 | ~14 |
| Thixatrope (wt. % paste) | 1 | 1 | 1 | 1 | 1 |
| Paste Deposit (g) | 0.214 | 0.192 | 0.196 | 0.201 | 0.180 |
| Ag Mass (g) | 0.17 | 0.15 | 0.16 | 0.16 | 0.14 |

The resulting pastes were screen printed onto P-type solar cells, which were then fired and tested according to the parameters set forth in Example 1. Paste deposition for each of the exemplary pastes was weighed. Silver deposition was calculated based on the silver content of each of the pastes. Exemplary pastes show optimal amount of paste deposit, as well as silver deposit.

The electrical performance of the five exemplary pastes was analyzed, and all data is set forth in Table 4. The exemplary pastes containing a higher amount of both types of sub-micron silver powders (Pastes 26L and 26N) exhibited excellent electrical performance. The efficiency and fill factor of the exemplary pastes having the sub-micron silver component were higher than those of Paste 26G (having no sub-micron silver). The various resistance measurements were also acceptable.

TABLE 4
Electrical Performance of Second Set of Exemplary Pastes

| | 26G | 26K | 26L | 26M | 26N |
|---|---|---|---|---|---|
| Eff (%) | 17.650 | 17.652 | 17.761 | 17.746 | 17.881 |
| FE (%) | 78.075 | 78.197 | 78.482 | 77.910 | 78.154 |
| Rs (Ω) | 0.00486 | 0.00488 | 0.00477 | 0.00496 | 0.00486 |
| Rs3 (Ω) | 0.00365 | 0.00396 | 0.00376 | 0.00418 | 0.00392 |
| Rg (mΩ) | 25.918 | 27.850 | 26.368 | 27.335 | 27.103 |

### EXAMPLE 3

As shown in Table 5, a third set of exemplary pastes (referred to as 26O, 26R, 26N and 26S) was prepared in order to illustrate the effect of adding an increased amount of de-agglomerated and agglomerated sub-micron silver powder as compared to Example 2. The same glass frit and vehicle formulation were used in each exemplary paste, with some variation to the amounts of each. Once the components of the pastes were mixed, they were then milled using a three-roll mill until becoming a dispersed uniform paste.

TABLE 5
Composition of Third Set of Exemplary Pastes

| | 26O | 26R | 26N | 26S |
|---|---|---|---|---|
| Ag (wt. % paste) | 73 | 75 | 77 | 78 |
| Particle size >1 μm | | | | |
| Ag Powder, SA (wt. % paste) | 6.5 | 7 | — | — |
| Ag Powder, SB (wt. % paste) | — | — | 3 | 3.5 |
| Glass frit (wt. % paste) | 4 | 4 | 4 | 4 |
| Organic vehicle (wt. % paste) | 14 | 12 | 14 | 12 |
| Thixatrope (wt. % paste) | 1 | 2 | 1 | 2 |
| Paste Deposit (g) | 0.22 | 0.22 | 0.22 | 0.23 |
| Ag Mass (g) | 0.17 | 0.18 | 0.18 | 0.19 |

The resulting pastes were screen printed onto P-type solar cells, which were then fired and tested according to the parameters set forth in Example 1. Paste deposition for each of the exemplary pastes was weighed. Silver deposition was calculated based on the silver content of each of the pastes. Exemplary pastes show optimal amount of paste deposit, as well as silver deposit.

The electrical performance of the five exemplary pastes was analyzed, and the resulting data is set forth in Table 6. All of the exemplary pastes exhibited optimal electrical performance, including excellent efficiency values.

TABLE 6
Electrical Performance Third Set of Exemplary Pastes

| | 26O | 26R | 26N | 26S |
|---|---|---|---|---|
| Eff (%) | 17.672 | 17.768 | 17.712 | 17.873 |
| ft (%) | 78.436 | 78.906 | 78.775 | 78.780 |
| Rs (Ω) | 0.00501 | 0.00472 | 0.00480 | 0.00474 |
| Rs3 (Ω) | 0.00360 | 0.00329 | 0.00347 | 0.00342 |
| Rg (mΩ) | 27.831 | 20.284 | 26.395 | 22.211 |

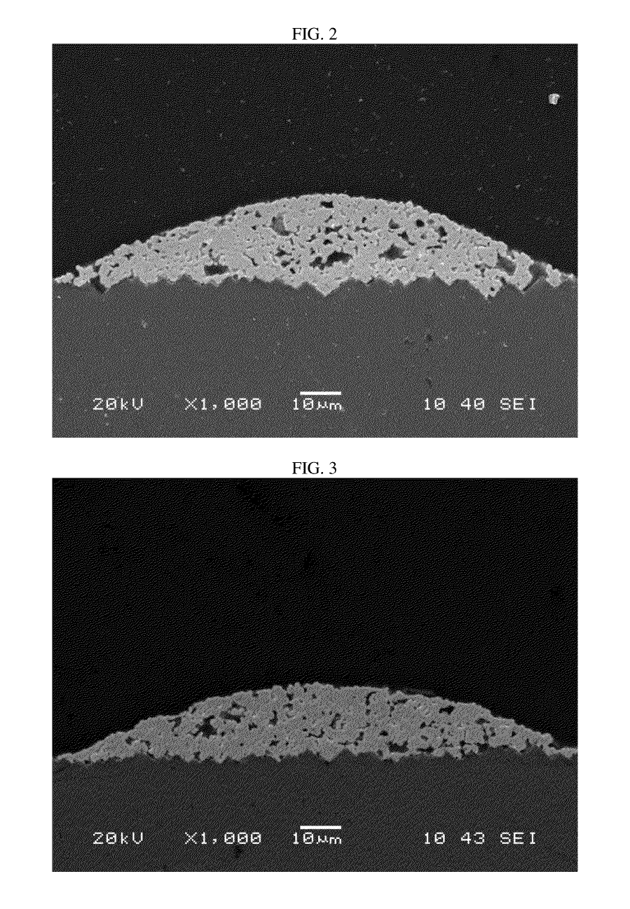

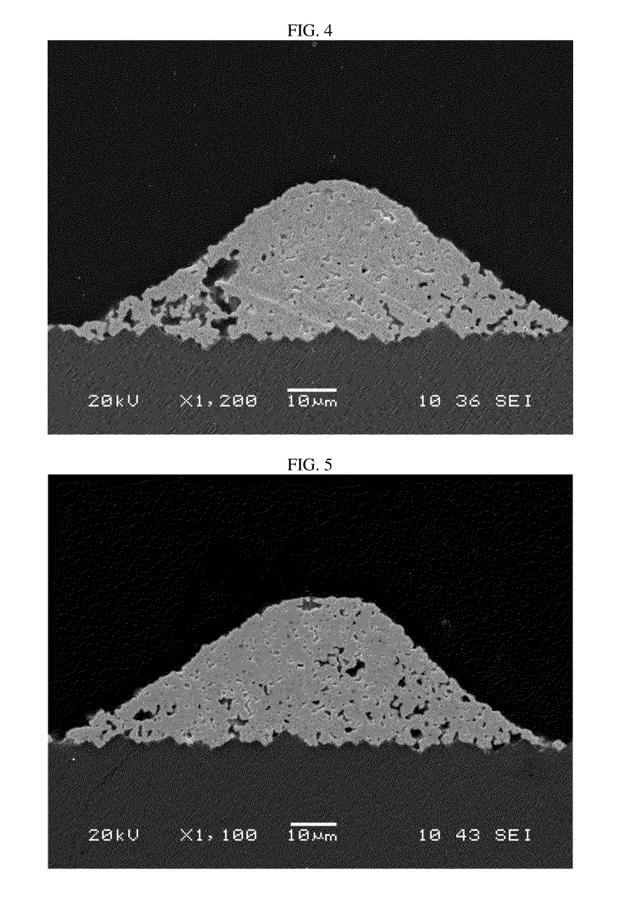

As shown in FIGS. 2-5, Pastes 26R and 26S resulted in the best printed line, having a high aspect ratio and very low porosity. Pastes 26N and 26O exhibited much lower aspect ratios and a higher degree of porosity, which explains the increase in series and grid resistance with these pastes.

These and other advantages of the invention will be apparent to those skilled in the art from the foregoing specification. Accordingly, it will be recognized by those skilled in the art that changes or modifications may be made to the above described embodiments without departing from the broad inventive concepts of the invention. Specific dimensions of any particular embodiment are described for illustration purposes only. It should therefore be understood that this invention is not limited to the particular embodiments described herein, but is intended to include all changes and modifications that are within the scope and spirit of the invention.

What is claimed:

1. An electroconductive paste for use in forming surface electrodes on solar cells comprising:
a silver component comprising a first silver particle having an average particle size of less than 1 micron and a specific surface area of greater than 2.4 m²/g;
glass frit; and
an organic vehicle.

2. The electroconductive paste of claim 1, wherein the first silver particle has an average particle size of 0.05-1 micron and a specific surface area of greater than 2.4 m²/g and less than or equal to 20 m²/g.

3. The electroconductive paste of claim 2, wherein the first silver particle has an average particle size of 0.1-0.8 micron and a specific surface area of greater than 2.4 m²/g and less than or equal to 10 m²/g.

4. The electroconductive paste of claim 3, wherein the first silver particle has an average particle size of 0.1-0.5 micron and a specific surface area of greater than 2.4 m²/g and less than or equal to 5 m²/g.

5. The electroconductive paste of claim 1, wherein the silver component further comprising a second silver particle.

6. The electroconductive paste of claim 5, wherein the second silver particle has an average particle size greater than 1 micron and a specific surface area of less than 2 m²/g.

7. The electroconductive paste of claim 6, wherein the second silver particle has an average particle size of 1-50 microns and a specific surface area of 0.1-2 m²/g.

8. The electroconductive paste of claim 7, wherein the second silver particle has an average particle size of 1-20 microns and a specific surface area of 0.1-1.5 m²/g.

9. The electroconductive paste of claim 1, wherein total silver component is less than 83.5 wt. % of paste.

10. The electroconductive paste of claim 1, wherein the first silver particle is about 0.01-10 wt. % of paste.

11. The electroconductive paste of claim 5, wherein the second silver particle is about 60-90 wt. % of paste.

12. The electroconductive paste of claim 1, wherein the glass frit is about 5 wt. % of paste.

13. The electroconductive paste of claim 1, wherein the glass frit comprises lead oxide.

14. The electroconductive paste of claim 1, wherein the organic vehicle is about 1-35 wt. % of paste.

15. The electroconductive paste of claim 1, wherein the organic vehicle comprises a binder, a surfactant, an organic solvent, and a thixatropic agent.

16. The electroconductive paste of claim 15, wherein the thixatropic agent is about 0.01-20 wt. % of the organic vehicle.

17. The electroconductive paste of claim 16, wherein the thixatropic agent is about 5-20 wt. % of the organic vehicle.

18. An electroconductive paste for use in forming surface electrodes on solar cells comprising:
conductive metal particles, which are 40-90 wt. % of paste;
glass frit; and
an organic vehicle, wherein the organic vehicle comprising a binder, a surfactant,
an organic solvent, and a thixatropic agent, wherein the thixatropic agent is above 1 wt. % of the paste.

19. A solar cell comprising:
a silicon wafer; and
a surface electrode produced from an electroconductive paste according to claim 1.

20. A solar cell comprising:
a silicon wafer; and
a surface electrode produced from an electroconductive paste according to claim 18.

21. A solar cell module comprising electrically interconnected solar cells as in claim 19.

22. A solar cell module comprising electrically interconnected solar cells as in claim 20.

23. A method of producing a solar cell, comprising the steps of:
providing a silicon wafer;
applying an electroconductive paste according to claim 1 to the silicon wafer; and
firing the silicon wafer according to an appropriate profile.

24. A method of producing a solar cell, comprising the steps of:
providing a silicon wafer;
applying an electroconductive paste according to claim 18 to the silicon wafer; and
firing the silicon wafer according to an appropriate profile.
